(19) United States
(12) Patent Application Publication
(10) Pub. No.: US 2012/0068147 A1
(43) Pub. Date: Mar. 22, 2012

(54) PHASE CHANGE MEMORY DEVICE AND FABRICATION THEREOF

(75) Inventors: Jen-Chi CHUANG, Hsinchu County (TW); Ming-Jeng HUANG, Taichung City (TW); Chien-Min LEE, Kaohsiung City (TW); Jia-Yo LIN, Hsinchu City (TW); Min-Chih WANG, Taipei County (TW)

(73) Assignee: POWERCHIP SEMICONDUCTOR CORP., HSIN-CHU (TW)

(21) Appl. No.: 13/304,187

(22) Filed: Nov. 23, 2011

Related U.S. Application Data
(62) Division of application No. 12/468,699, filed on May 19, 2009.

(30) Foreign Application Priority Data
Feb. 20, 2009 (TW) TW98105420

(51) Int. Cl. H01L 47/00

(52) U.S. Cl. 257/4; 257/E47.001

(57) ABSTRACT

A method for forming a phase change memory device is disclosed. A substrate with a bottom electrode thereon is provided. A heating electrode and a dielectric layer are formed on the bottom electrode, wherein the heating electrode is surrounded by the dielectric layer. The heating electrode is etched to form recess in the dielectric layer. A phase change material is deposited on the dielectric layer, filling into the recess. The phase change material is polished to remove a portion of the phase change material exceeding the surface of the dielectric layer and a phase change layer is formed confined in the recess of the dielectric layer. A top electrode is formed on the phase change layer and the dielectric layer.

### CROSS REFERENCE TO RELATED APPLICATIONS

This Application claims priority of Taiwan Patent Application No. 98105420, filed on Feb. 20, 2009, the entirety of which is incorporated by reference herein.

### BACKGROUND OF THE INVENTION

1. Field of the Invention

The invention relates to a semiconductor device and fabrication thereof, and more particularly relates to a phase change memory device and fabrication thereof.

2. Description of the Related Art

Phase change memory cells have many advantages, such as fast speeds, low power consumption, high capacities, robust endurance, easy embedness in logic ICs, and low costs. Thus, phase change memories serve as stand-alone devices or embedded memory devices with high integrity. Due to the described advantages, phase change memories are considered as the most promising candidate for next-generation nonvolatile semiconductor memories, replacing more commercialized volatile memories, such as SRAMs or DRAMs, and non-volatile memories, such as flash memories.

Binary state switching in a phase change memory cell is accomplished by a fast and reversible amorphous phase and crystalline phase transformation in an active region of chalcogenide material, such as Ge₂Sb₂Te₅ (GST). The transformations, which are induced by pulsed Joule heating, results in either a highly resistive RESET state or a low-resistance SET state, depending on, if the phase is amorphous or crystalline, respectively.

Current pulses with different durations and amplitudes may be used to program the phase change memory cell. For example, the RESET current pulse with higher amplitude and shorter width, such as 0.6 mA with 50 ns, is applied to melt the GST alloy and the melted GST alloy is then rapidly quenched to be frozen to form the disordered structure (RESET state). The RESET state of the phase change memory cell has a higher resistance ranging from 10⁵ to 10⁷ ohm and the phase change memory cell presents a higher voltage when a current is applied for reading. On the other hand, the SET current pulse has lower amplitude and longer time (for example, 0.3 mA and 100 ns) so as to effectively crystallize the disordered GST alloy with sufficient time. Due to low-resistance SET state ranging from 10² to 10⁴ ohm, the phase change memory cell presents a lower voltage when a current is applied for reading.

Referring to FIG. 1, which shows a conventional phase change memory device, including, a bottom electrode 102, a heating electrode 104, a phase change layer 106, a barrier layer 108, a top electrode contact 110, and a top electrode 112. The features of the phase change layer 106 are defined by a photolithography process, and a phase change region is close to the edge of the phase change layer 106. However, the conventional phase change memory device has drawbacks as follows. First, photolithography process size limitations hinder further miniaturization of the phase change layer 106 of the conventional phase change memory device. Second, issues from damage to the sidewalls of the phase change layer 106 when the phase change layer is patterned by etching are increased as the phase change layer 106 is further miniaturized. Thus, for further miniaturization of the conventional phase change memory device, costs are increased and processes are made more complex.

Accordingly, a phase change memory device and fabrication thereof, wherein miniaturization is not limited by the current photolithography processes and influence from damage to the sidewalls of the phase change layer when the phase change layer is patterned by etching is decreased, are desired.

### BRIEF SUMMARY OF INVENTION

According to the issues described, the invention provides a method for forming a phase change memory device. A substrate with a bottom electrode thereon is provided. A heating electrode and a dielectric layer are formed on the bottom electrode, wherein the heating electrode is surrounded by the dielectric layer. The heating electrode is etched to form a recess in the dielectric layer. A phase change material is deposited on the dielectric layer, filling into the recess. The phase change material is polished to remove a portion of the phase change material exceeding the surface of the dielectric layer and a phase change layer is formed confined in the recess of the dielectric layer. A top electrode is formed on the phase change layer and the dielectric layer.

The invention further provides a phase change memory device, including a bottom electrode, a dielectric layer on the bottom electrode, a confined structure including a heating electrode and a phase change layer in the dielectric layer and a top electrode on the phase change layer and the dielectric layer.

### BRIEF DESCRIPTION OF DRAWINGS

The invention can be more fully understood by reading the subsequent detailed description and examples with references made to the accompanying drawings, wherein:

FIG. 1 shows a conventional phase change memory device;

FIGS. 2A˜2F show intermediate cross sections of a device to illustrate a method for forming a bottle-shaped electrode;

FIGS. 3A˜3E show intermediate cross sections of a phase change memory device with a bottle-shaped heating electrode of an embodiment of the invention;

FIGS. 4A˜4F show intermediate cross sections of a phase change memory device with a bottle-shaped heating electrode of another embodiment of the invention; and

FIGS. 5A˜5E show intermediate cross sections of a phase change memory device with column-shaped heating electrodes of further another embodiment of the invention.

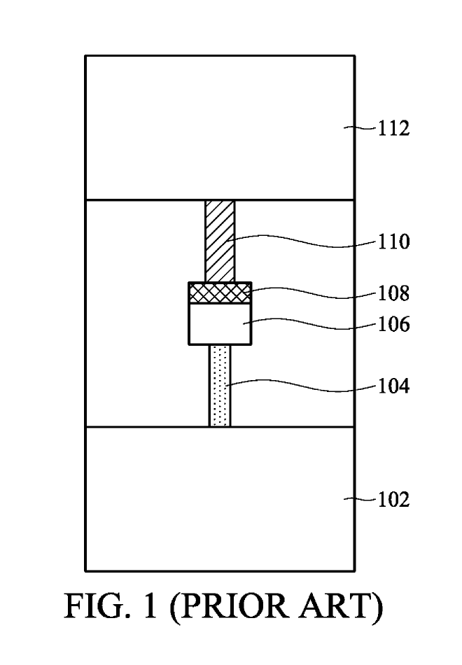

### DETAILED DESCRIPTION OF INVENTION

The following descriptions are of the contemplated mode of carrying out the invention. This description is made for the purpose of illustrating the general principles of the invention and should not be taken in a limiting sense.

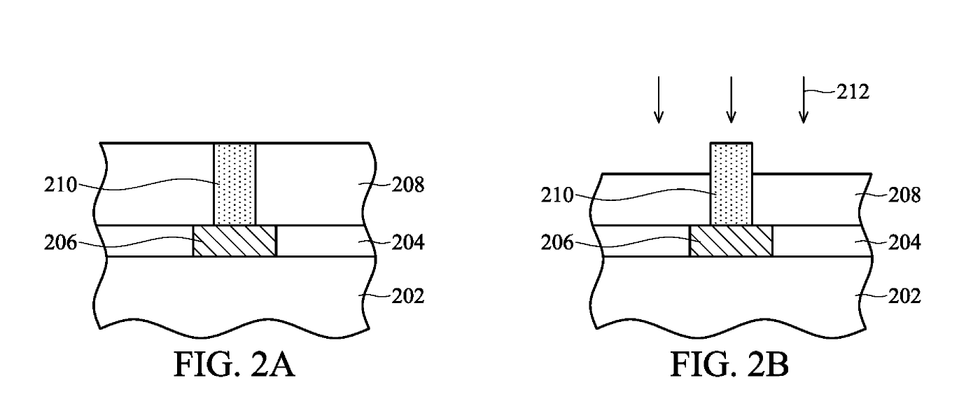

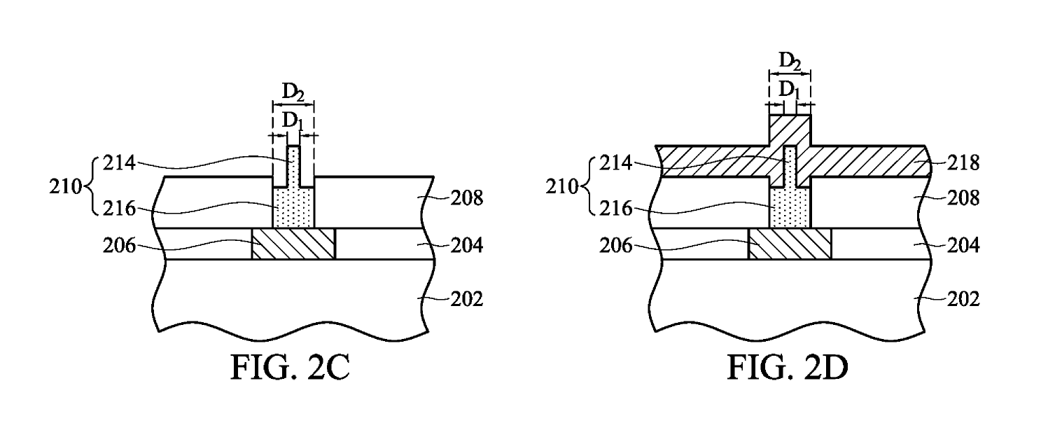

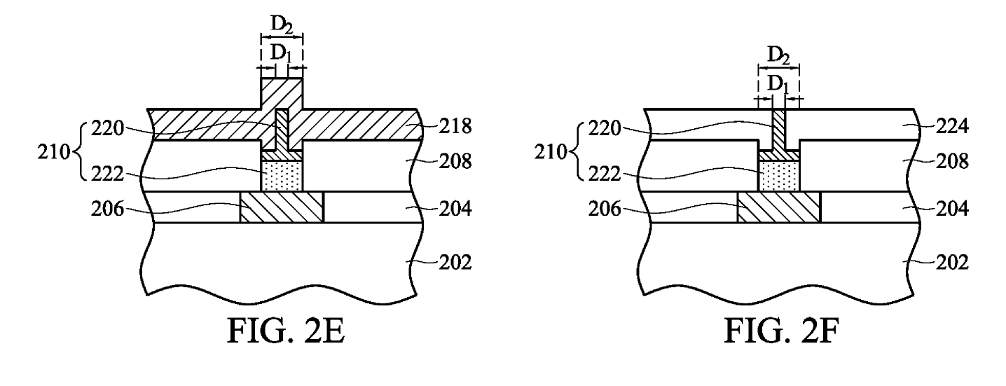

A method for forming a bottle-shaped electrode is described in accordance with FIGS. 2A˜2F. First, referring to FIG. 2A, a substrate 202 is provided and a bottom electrode 206, such as Ti, TiN, TiW, W, WN, WSi, TaN or doped polysilicon, is formed thereon. A first dielectric layer 204 is deposited on the bottom electrode 206 and the substrate 202, and a planarizing process is performed to remove a portion of the first dielectric layer 204 exceeding the surface of the bottom electrode 206. A heating electrode 210 formed of doped polysilicon is formed on the bottom electrode 206. A second dielectric layer 208 is deposited on the heating electrode 210 and the first dielectric layer 204, and a planarizing process is then performed to remove a portion of the second dielectric layer 208 exceeding the surface of the heating electrode 210. Referring to FIG. 2B, an etching process 212 is performed to selectively remove a portion of the second dielectric layer 208 for the second dielectric layer 208 to have a top surface lower than the surface of the heating electrode 210. In other words, after the etching process 212, the heating electrode 210 protrudes out the surface of the second dielectric layer 208. Referring to FIG. 2C, another etching process, such as an isotropic wet etching process, is performed to etch the exposed portion of the heating electrode 210 to form a reversed T shape from a cross section view. Specifically, the etched heating electrode has a first portion 214 and a second portion 216. The diameter D₁ of the first portion 214 is smaller than the diameter D₂ of the second portion 216. Referring to FIG. 2D, a metal layer 218 is deposited on the heating electrode 210 and the second dielectric layer 208. Referring to FIG. 2E, an annealing process is performed for the heating electrode 210 to silicide with the contacted metal layer 218. Thus, the heating electrode 210 comprises a third portion 220 formed of metal silicide and a fourth portion 222 formed without metal silicide, wherein the third portion 220 has a reversed T shape from a cross section view. Referring to FIG. 2F, the portion of the metal layer 218 not reacted is removed and a third dielectric layer 224 is deposited on the heating electrode 210 and the second dielectric layer 208, and a planarizing process is performed to remove a portion of the third dielectric layer 224 exceeding the surface of the heating electrode 210. The embodiment thus forms a bottle-shaped heating electrode 210 with a top portion and a bottom portion, wherein the top portion diameter D₁ is smaller than a bottom portion diameter D₂.

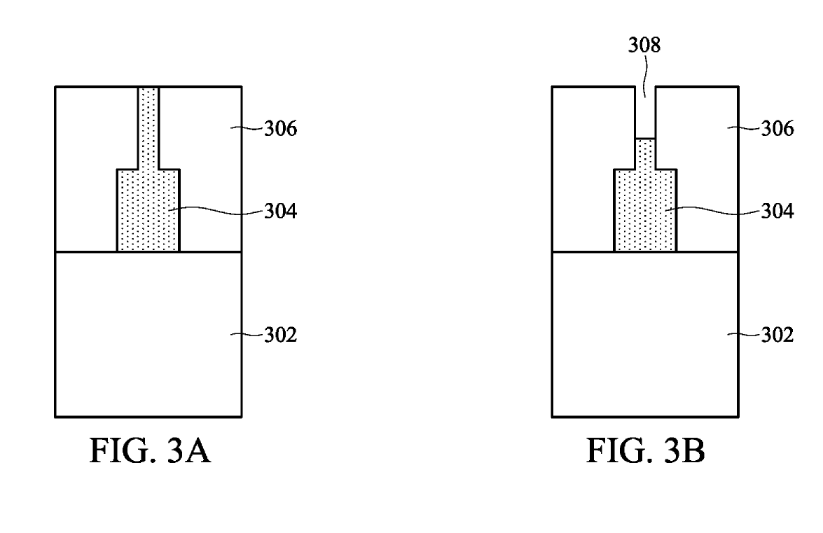

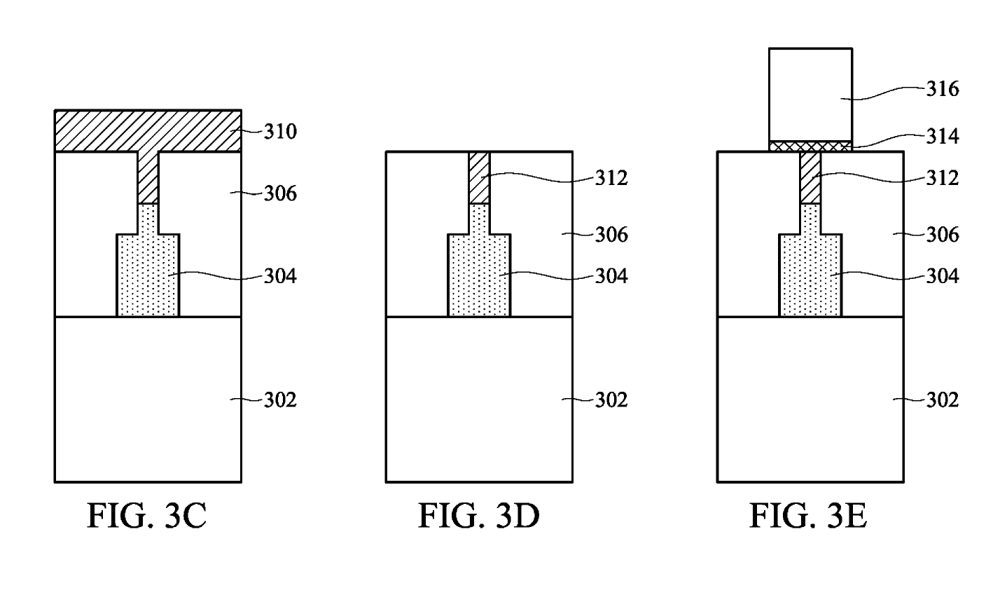

A method for forming a phase change memory device with a bottle-shaped heating electrode is illustrated in accordance with FIG. 3A˜3E. It should be understood that the bottle-shaped heating electrode can be formed by the aforementioned method, but is not limited thereto. Referring to FIG. 3A, a bottom electrode 302 is provided and a bottle-shaped heating electrode 304 is formed in a dielectric layer 306 by the method described in the aforementioned embodiment. Referring to FIG. 3B, an etching back process, such as wet etching process, is performed to etch a portion of the heating electrode 304 to form a recess 308 in the dielectric layer 306. Referring to FIG. 3C, a phase change material 310 is blanketly deposited on the dielectric layer 306 and filled, by for example by CVD or PVD, into the recess 308 formed by etching back of the heating electrode 306. The phase change material comprises a chalcogenide compound, such as Ge—Te—Sb chalcogenide ternary compound or doped chalcogenide multicomponent. Referring to FIG. 3D, a planarizing process, such as a chemical mechanical polishing (CMP) process, is performed to remove a portion of the phase change material exceeding a top surface of the dielectric layer 306 to form a phase change layer 312 in the recess. After the polishing step, the surface of the phase change layer 312 is substantially co-planar with the surface of the dielectric layer 306. Note that the heating electrode 304 and the phase change layer 312 constitute a confined structure in the dielectric layer 306. Referring to FIG. 3E, a barrier layer 314, made from material such as titanium nitride, is formed on the phase change layer 312 and the dielectric layer 306. Next, a top electrode 316 is formed on the barrier layer 314. It is noted that the embodiment uses a self-aligned method to form the phase change layer 312 and not a photolithography process. Thus, further device miniaturization is not limited by size limitation of the photolithography process. In addition, damage to sidewalls of the phase change layers are eliminated because unlike prior technology, the phase change layers of the invention are not etched to form the sidewalls. Furthermore, the confined structure of the phase change layer and the heating electrode of the invention provides less reset current than the conventional phase change memory device.

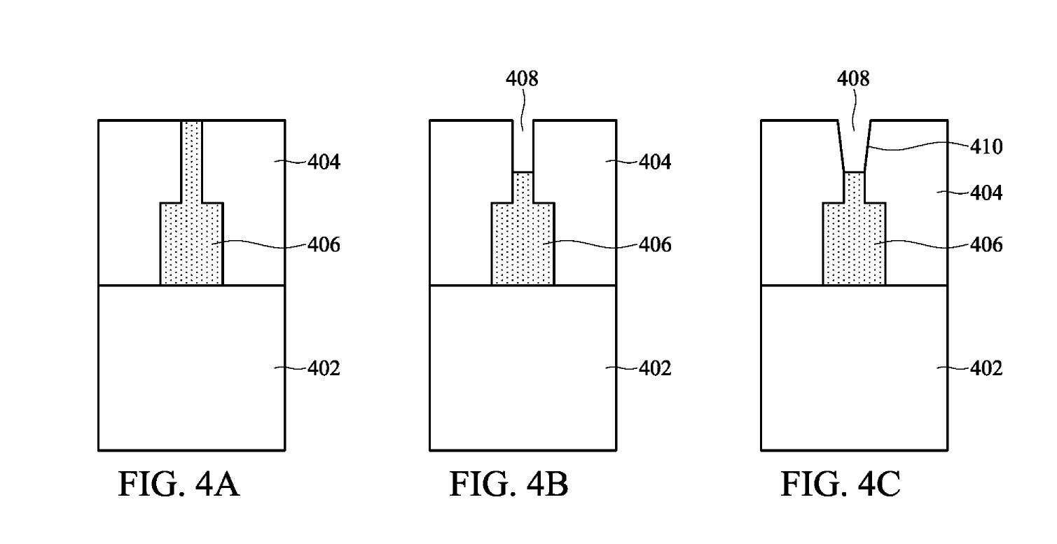

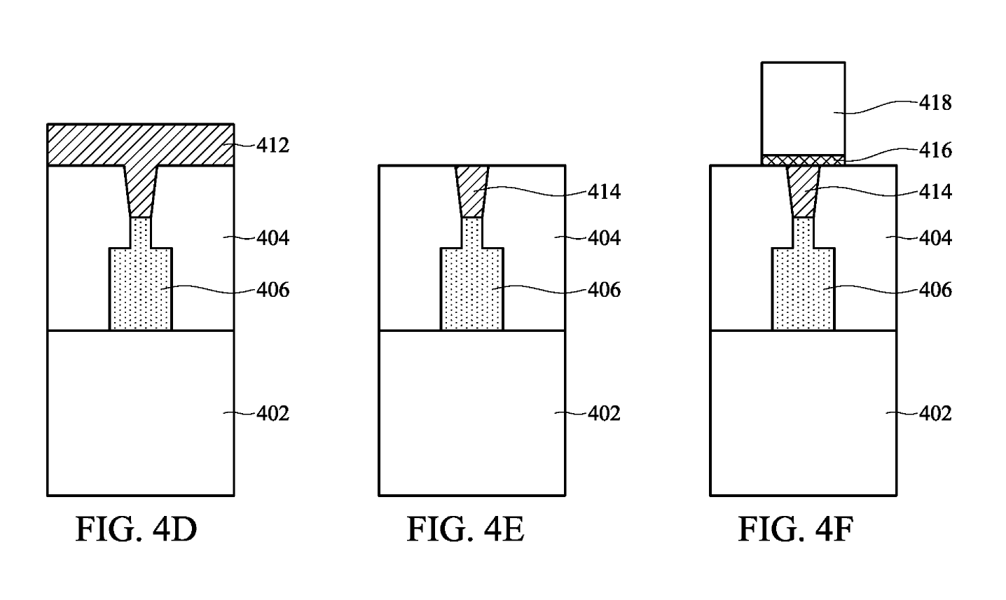

A method for forming a phase change memory device with a bottle-shaped heating electrode is illustrated in accordance with FIG. 4A˜4F. Unlike the embodiment illustrated in FIG. 3A˜3E, the embodiment forms a confined and reverse triangle shaped phase change structure. Referring to FIG. 4A, a bottom electrode 402 is provided and a bottle-shaped heating electrode 406 is formed in a dielectric layer 404. Referring to FIG. 4B, an etching back process, such as wet etching process, is performed to etch a portion of the heating electrode 406 to form a recess 408 in the dielectric layer 404. Referring to FIG. 4C, an anisotropic etching process is performed to expand the top of the recess 408 and a tilted sidewall 410 is obtained. The purpose of expanding the top of the recess 408 is for the subsequent depositing process, wherein material is filled more easily into the recess 408. Thus, problems associated with incomplete filling of the gap can be reduced. Referring to FIG. 4D, a phase change material 412 is blanketly deposited on the dielectric layer 404 and filled into the recess 408, by for example CVD or PVD, formed by etching back the heating electrode 406. Referring to FIG. 4E, a planarizing process, such as chemical mechanical polishing (CMP) process, is performed to remove a portion of the phase change material exceeding a top surface of the dielectric layer 404 to form a phase change layer 414 in the recess 404. Note that the phase change layer 414 formed in the step is substantially reverse triangle shaped. Referring to FIG. 4F, a barrier layer 416, made of material such as titanium nitride, is formed on the phase change layer 414 and the dielectric layer 404. Next, a top electrode 418 is formed on the barrier layer 416. Thus, further device miniaturization is not limited by size limitation of the photolithography process. In addition, the confined structure of the triangle-shaped phase change layer 414 and the heating electrode 406 of the invention provides less reset current than the conventional phase change memory device.

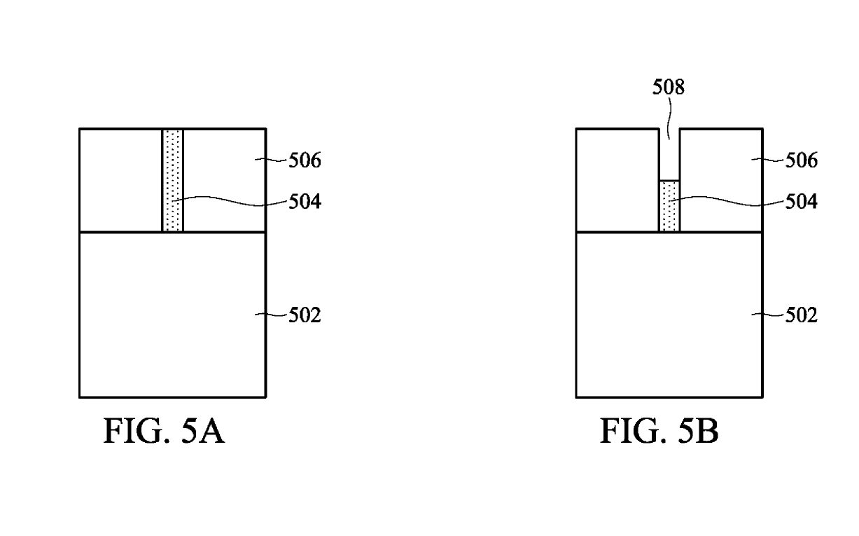

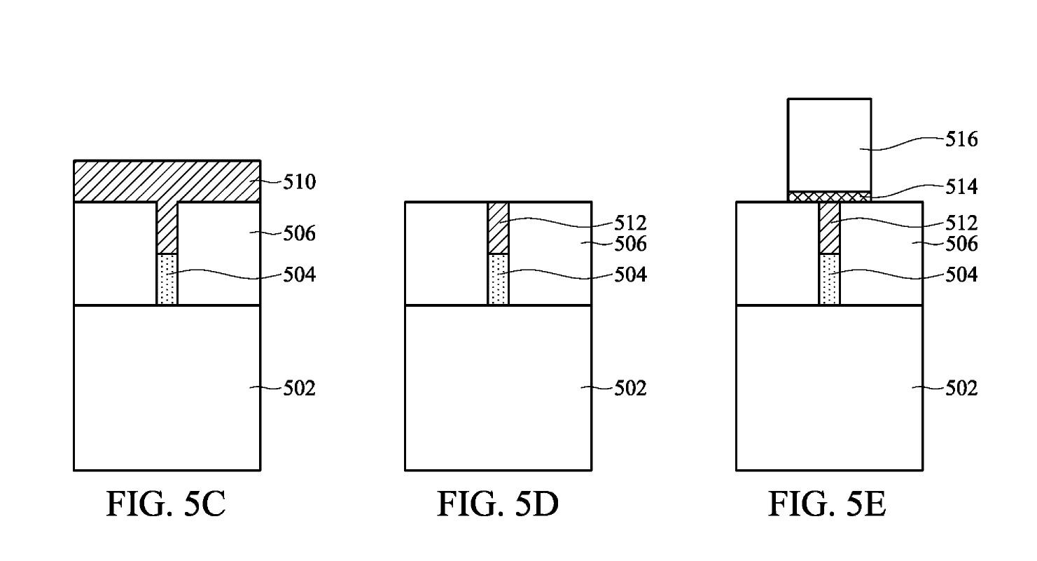

The heating electrode of the invention is not limited to being bottle shaped. It can be column-shaped or other shapes. A method for forming a phase change memory device with column-shaped heating electrode is illustrated in accordance with FIG. 5A˜5E. Referring to FIG. 5A, a bottom electrode 502 is provided and a column-shaped heating electrode 504 is formed in a dielectric layer 506. Referring to FIG. 5B, an etching back process, such as wet etching process, is performed to etch a portion of the heating electrode 504 to form a recess 508 in the dielectric layer 506. Referring to FIG. 5C, a phase change material 510 is blanketly deposited on the dielectric layer 506 and filled into the recess 508, by for example CVD or PVD, formed by etching back the heating electrode 504. Referring to FIG. 5D, a planarizing process, such as a chemical mechanical polishing (CMP) process, is performed to remove a portion of the phase change material exceeding a top surface of the dielectric layer 506 to form a phase change layer 512 in the recess 508. Note that the heating electrode 512 and the phase change layer 504 formed in the step constitute a confined structure in the dielectric layer 506. Referring to FIG. 5E, a barrier layer 514, made of material such as titanium nitride, is formed on the phase change layer 512 and the dielectric layer 506. Next, a top electrode 516 is formed on the barrier layer 514.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1-15. (canceled)

16. A phase change memory device, comprising:
a bottom electrode;
a dielectric layer on the bottom electrode;
a heating electrode and a phase change layer in the dielectric layer, wherein the phase change layer is confined in a recess above the heating electrode, and a surface of the phase change layer is co-planar with a surface of the dielectric layer; and
a top electrode on the surfaces of the phase change layer and the dielectric layer.

17. The phase change memory device as claimed in claim 16, wherein the phase change layer confined in the recess has a reverse triangle shape.

18. The phase change memory device as claimed in claim 16, wherein the phase change layer confined in the recess has a column shape.

19. The phase change memory device as claimed in claim 16, further comprising a barrier layer disposed between the top electrode and the phase change layer.
